(19) United States
(12) Patent Application Publication
(10) Pub. No.: US 2023/0389402 A1
(43) Pub. Date: Nov. 30, 2023

(54) DISPLAY DEVICE

(71) Applicant: Samsung Display Co., LTD., Yongin-si (KR)

(72) Inventors: JONGWON LEE, Yongin-si (KR); SEUNG CHEOL KIM, Yongin-si (KR); Heung Su PARK, Yongin-si (KR); Chang-Min LEE, Yongin-si (KR); Hyun Shik LEE, Yongin-si (KR)

(73) Assignee: Samsung Display Co., LTD., Yongin-si (KR)

(21) Appl. No.: 18/296,481

(22) Filed: Apr. 6, 2023

(30) Foreign Application Priority Data
May 31, 2022 (KR) 10-2022-0066815

(51) Int. Cl. H10K 59/80; H10K 59/35

(52) U.S. Cl. CPC H10K 59/879; H10K 59/35; H10K 59/873

(57) ABSTRACT

A display device includes a light emitting device disposed on a substrate, a capping layer disposed on the light emitting device, and an encapsulation layer disposed on the capping layer. The capping layer includes a first surface facing the encapsulation layer, the first surface of the capping layer includes a protrusion protruding toward the encapsulation layer, and a height of the protrusion is greater than or equal to about 600 angstroms in a cross-sectional view.

### CROSS-REFERENCE TO RELATED APPLICATION(S)

This application claims priority to and benefits of Korean Patent Application No. 10-2022-0066815 under 35 U.S.C. § 119, filed on May 31, 2022, in the Korean Intellectual Property Office, the entire contents of which are incorporated herein by reference.

### BACKGROUND

### 1. Technical Field

The disclosure relates to a display device.

### 2. Description of the Related Art

A light emitting device is a device having a characteristic in which electrical energy is converted into light energy. Examples of such a light emitting device include an organic light emitting device using an organic material for an emission layer, and a quantum dot light emitting device using a quantum dot for an emission layer.

A light emitting device may include a first electrode and a second electrode that overlap each other, and a hole transport region, an emission layer, and an electron transport region, which are disposed between the first electrode and the second electrode. Holes injected from the first electrode move to the emission layer through the hole transport region, and electrons injected from the second electrode move to the emission layer through the electron transport region. The holes and electrons are combined in the emission layer region to generate excitons. Light is generated as the excitons are changed into a ground state from an exited state.

The above information disclosed in this Background section is only for enhancement of understanding of the background of the disclosure, and therefore it may contain information that does not form the prior art that is already known in this country to a person of ordinary skill in the art.

### SUMMARY

Embodiments provide a display device in which light extraction efficiency and lifespan of a light emitting device are improved without an increase in a driving voltage.

An embodiment provides a display device that may include a light emitting device disposed on a substrate, a capping layer disposed on the light emitting device, and an encapsulation layer disposed on the capping layer. The capping layer may include a first surface facing the encapsulation layer, the first surface of the capping layer may include a protrusion protruding toward the encapsulation layer, and a height of the protrusion may be greater than or equal to about 600 angstroms in a cross-sectional view.

An area of the protrusion may be greater than or equal to about 1 square micrometer in a plan view.

The capping layer may include at least one of a compound represented by Chemical Formula 1 and a compound represented by Chemical Formula 2:

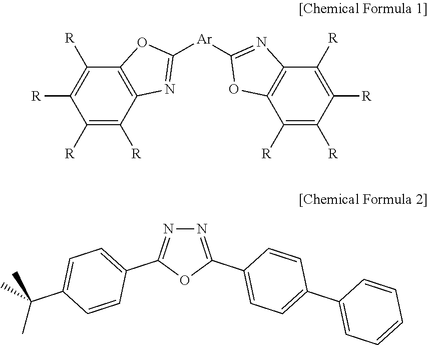

In Chemical Formula 1, Ar may be an aryl group having 6 to 20 carbon atoms, and each R may independently be hydrogen, an alkyl group having 1 to 20 carbon atoms, an aryl group having 6 to 20 carbon atoms, a heteroaryl group having 5 to 20 carbon atoms, a halogen, a nitro group, CN, or an amine group.

A thickness of the capping layer may be in a range of about 300 angstroms to about 1,000 angstroms in a cross-sectional view.

Another embodiment provides a display device that may include a light emitting device disposed on a substrate, a capping layer disposed on the light emitting device, and an encapsulation layer disposed on the capping layer. The capping layer may include a first capping layer and a second capping layer, the first capping layer may include a protrusion, and each of the first capping layer and the second capping layer may include an organic material.

The light emitting device may include a first electrode, an emission layer disposed on the first electrode, and a second electrode disposed on the emission layer.

The first capping layer may be disposed on the second electrode, and the second capping layer may be disposed on the first capping layer.

The second capping layer may cover the first capping layer.

The first capping layer may expose a portion of the second electrode, and the second capping layer may cover the second electrode and the first capping layer.

The second capping layer may be disposed on the second electrode, and the first capping layer may be disposed on the second capping layer.

The first capping layer may expose a portion of the second capping layer.

The first capping layer may include at least one of a compound represented by Chemical Formula 1 and a compound represented by Chemical Formula 2:

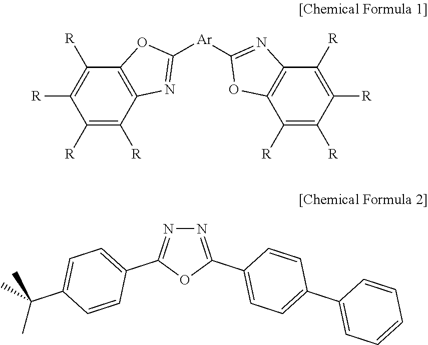

In Chemical Formula 1, Ar may be an aryl group having 6 to 20 carbon atoms, and each R may independently be hydrogen, an alkyl group having 1 to 20 carbon atoms, an aryl group having 6 to 20 carbon atoms, a heteroaryl group having 5 to 20 carbon atoms, a halogen, a nitro group, CN, or an amine group.

The second capping layer may include a compound represented by Chemical Formula 3:

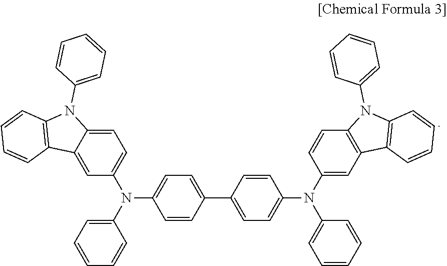 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

An area of the protrusion may be greater than or equal to about 1 square micrometer in a plan view, and a height of the first protrusion may be greater than or equal to about 600 angstroms in a cross-sectional view.

A thickness of the first capping layer may be in a range of about 300 angstroms to about 1,000 angstroms in a cross-sectional view.

A thickness of the second capping layer may be greater than or equal to about 300 angstroms in a cross-sectional view.

The light emitting device may include a first light emitting device that emits light of a first color, and a second light emitting device that emits light of a second color.

The first color and the second color may be different.

The first light emitting device may emit blue light, and the second light emitting device may emit green light.

The first light emitting device may include a first emission layer, the second light emitting device may include a second emission layer, and at least one of the first emission layer and the second emission layer may include a quantum dot.

According to the embodiments, it is possible to provide a display device in which light extraction efficiency and lifespan of a light emitting device are improved without an increase in a driving voltage.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will become more apparent by describing in detail embodiments thereof with reference to the attached drawings, in which:

FIG. 1 illustrates a schematic cross-sectional view of a light emitting device and a capping layer according to an embodiment.

FIG. 2 illustrates a schematic cross-sectional view of a light emitting device and a capping layer according to an embodiment.

FIG. 3 illustrates a schematic cross-sectional view of a light emitting device and a capping layer according to an embodiment.

FIG. 4 illustrates a schematic cross-sectional view of a light emitting device and a capping layer according to an embodiment.

FIG. 5 illustrates an exploded perspective view of a display device according to an embodiment.

FIG. 6 illustrates a schematic cross-sectional view of a display panel according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

In order to clearly describe the disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements.

Spatially relative terms, such as “beneath”, “below”, “under”, “lower”, “above”, “upper”, “over”, “higher”, “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below”, for example, can encompass both an orientation of above and below. Furthermore, the apparatus may be otherwise oriented (e.g., rotated 90 degrees or at other orientations), and, as such, the spatially relative descriptors used herein interpreted accordingly.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

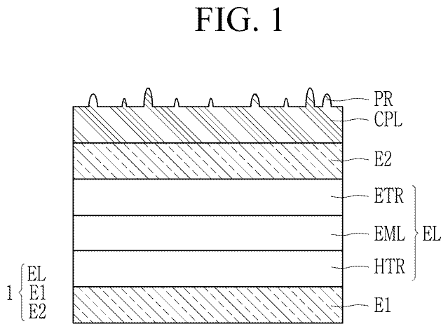

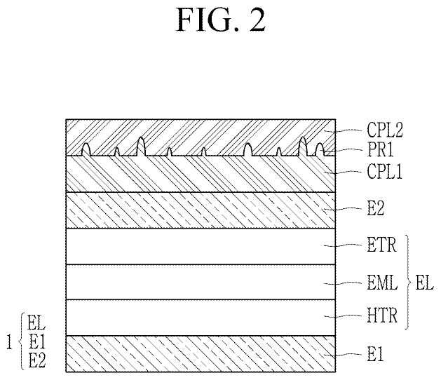

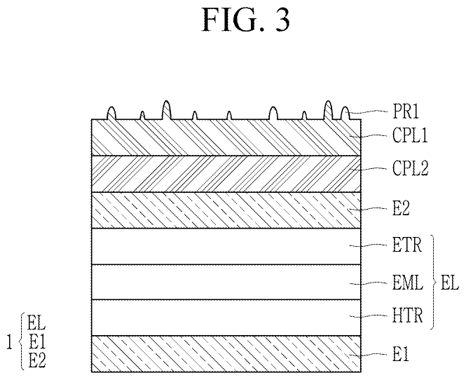

Hereinafter, a light emitting device according to an embodiment and a capping layer positioned on the light emitting device will be described with reference to FIG. 1 to FIG. 3. FIG. 1 illustrates a schematic cross-sectional view of a light emitting device and a capping layer according to an embodiment, FIG. 2 illustrates a schematic cross-sectional view of a light emitting device and a capping layer according to an embodiment, and FIG. 3 illustrates a schematic cross-sectional view of a light emitting device and a capping layer according to an embodiment.

Referring to FIG. 1, a light emitting device 1 may include a first electrode E1, a second electrode E2, and a light emitting unit EL disposed between the first electrode E1 and the second electrode E2.

The light emitting device 1 according to the embodiment of the disclosure may be a top emission type, and first electrode E1 may be an anode and the second electrode E2 may be a cathode. The light emitting device 1 according to another embodiment of the disclosure may be a bottom emission type, and the first electrode E1 may be a cathode and the second electrode E2 may be an anode. In the light emitting device 1 according to the embodiment of the disclosure, the first electrode E 1 may be a reflective electrode, and the second electrode E2 may be a transmissive or transflective electrode, so the light emitting device 1 emits light in a direction from the first electrode E1 to the second electrode E2. Hereinafter, a case in which the light emitting device is a top emission type will be described.

The first electrode E 1 may be formed, for example, by providing a material for the first electrode on a substrate by using a deposition method or a sputtering method. In case that the first electrode E1 is an anode, a material for the first electrode may be selected from materials having a high work function to facilitate hole injection.

The first electrode E1 may be a reflective electrode, a transflective electrode, or a transmissive electrode. In order to form the first electrode E1, which is a transmissive electrode, the material for the first electrode may include an indium tin oxide (ITO), an indium zinc oxide (IZO), a tin oxide (SnO₂), a zinc oxide (ZnO), or a combination thereof, but is not limited thereto. In another embodiment, in order to form the first electrode E1, which is a transflective electrode or a reflective electrode, the material for the first electrode may include magnesium (Mg), silver (Ag), aluminum (Al), aluminum-lithium (Al—Li), calcium (Ca), magnesium-indium (Mg—In), magnesium-silver (Mg—Ag), or a combination thereof, but is not limited thereto.

The first electrode E1 may have a single-layered structure having a single layer, or a multi-layered structure having multiple layers. For example, the first electrode E 1 may have a three-layered structure of ITO/Ag/ITO, but is not limited thereto.

The light emitting unit EL may be disposed on the first electrode E 1. The embodiment including one light emitting unit EL is illustrated in the specification, but the disclosure is not limited thereto, and the light emitting device 1 according to the embodiment may include one or more light emitting units EL.

The light emitting unit EL may include an emission layer EML. The light emitting unit EL may include at least one of a hole transport region HTR and an electron transport region ETR. The hole transport region HTR may include a hole injection layer, a hole transport layer, an electron blocking layer, or a combination thereof. The electron transport region ETR may include a hole blocking layer, an electron transport layer, an electron injection layer, or a combination thereof.

The hole transport region HTR may be formed by using a general method. For example, the hole transport region HTR may be formed by using various methods such as a vacuum deposition method, a spin coating method, a casting method, a Langmuir-Blodgett (LB) method, an inkjet printing method, a laser printing method, a laser induced thermal imaging (LITI) method, and the like.

The hole injection layer included in the hole transport region HTR may include a hole injection material. The hole injection material may include a phthalocyanine compound such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris{N,-(2-naphthyl)-N-phenylamino}-triphenylamine), PEDOT/PSS (poly(3,4-ethylenedioxythiophene)/poly(4-styrene sulfonate)), PANI/DB SA (polyaniline/dodecylbenzenesulfonic acid), PANI/CSA (polyaniline/camphor sulfonic acid), PANI/PSS (polyaniline/poly(4-styrenesulfonate)), NPB (N,N′-di(naphthalene-1-yl)-N,N′-diphenyl-benzidine), NPD (N,N′-di(1-naphthyl)-N,N′-diphenyl-(1,1′-biphenyl)-4,4′-diamine), polyether ketone (TPAPEK) containing triphenylamine, 4-isopropyl-4′-methyldiphenyliodonium [tetrakis(pentafluorophenyl)borate], HAT-CN (dipyrazino[2,3-f: 2′,3′-h] quinoxaline-2,3,6,7,10,11-hexacarbonitrile), and the like.

The hole transport layer included in the hole transport region HTR may include a hole transport material. The hole transport material may include a carbazole derivative such as N-phenylcarbazole and polyvinylcarbazole, fluorene-based derivatives, TPD (N,N′-bis(3-methylphenyl)-N,N′-diphenyl-[1,1-biphenyl]-4,4′-diamine), TC TA (4,4′,4″-tris(N-carbazolyl) triphenylamine), triphenylamine derivatives, NPB (N,N′-di(naphthalene-1-yl)-N,N′-diphenyl-benzidine), TAPC (4,4′-cyclohexylidene bis[N,N-bis(4-methylphenyl)benzenamine]), HMTPD (4,4′-bis [N,N′-(3-tolyl)amino]-3,3′-dimethylbiphenyl), mCP (1,3-bi s (N-carbazolyl)benzene), CzSi (9-(4-tert-butylphenyl)-3,6-bis(triphenylsilyl)-9H-carbazole), m-MTDATA (4,4′,4″-[tris(3-methylphenyl)phenylamino]triphenylamine), and the like.

A thickness of the hole transport region HTR may be in a range of about 100 Å to about A. For example, a thickness of the hole transport region HTR may be in a range of about 100 Å to about 5,000 Å. A thickness of the hole injection layer may be, for example, in a range of about 30 Å to about 1,000 Å, and a thickness of the hole transport layer may be in a range of about 30 Å to about 1,000 Å. In case that the thicknesses of the hole transport region HTR, the hole injection layer, and the hole transport layer satisfy the above-mentioned ranges, a satisfactory hole transport characteristic may be obtained without a substantial increase in driving voltage.

The electron blocking layer may be a layer that prevents electrons from leaking from the electron transport region ETR to the hole transport region HTR. A thickness of the electron blocking layer may be in a range of about 10 Å to about 1,000 Å. The electron blocking layer may include, for example, a carbazole derivative such as N-phenylcarbazole and polyvinylcarbazole, fluorene derivatives, triphenylamine derivatives such as TPD (N,N′-bis(3-methylphenyl)-N,N′-diphenyl-[1,1-biphenyl]-4,4′-diamine) and TCTA (4,4′,4″-tris(N-carbazolyl) triphenylamine), NPD (N,N′-di(naphthalene-1-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), or mCP.

The hole transport region HTR may further include a charge generating material for conductivity improvement in addition to the above-mentioned materials. The charge generating material may be uniformly or non-uniformly dispersed in the hole transport region HTR. The charge generating material may be, for example, a p-dopant. The p-dopant may be one of a quinone derivative, a metal oxide, and a cyano group-containing compound, but is not limited thereto. For example, non-limiting examples of the p-dopant may include quinone derivatives such as TCNQ (tetracyanoquinodimethane) and F4-TCNQ (2,3,5,6-tetrafluoro-7,7′,8,8′-tetracyanoquinodimethane), and a metal oxide such as tungsten oxide and molybdenum oxide, but are not limited thereto.

Each layer of the electron transport region ETR may be formed by using a general method. For example, the electron transport region ETR may be formed by using various methods such as a vacuum deposition method, a spin coating method, a casting method, a Langmuir-Blodgett (LB) method, an inkjet printing method, a laser printing method, a laser induced thermal imaging (LITI) method, and the like.

The electron injection layer included in the electron transport region ETR may include an electron injection material. The electron injection material may include a metal halide such as LiF, NaCl, CsF, RbCl, and RbI, a lanthanide metal such as Yb, a metal oxide such as Li2O and BaO, or lithium quinolate (LiQ), but the disclosure is not limited thereto. In another embodiment, the electron injection layer may include a material in which an electron transport material and an insulating organometallic salt are mixed. The organometallic salt may be a material having an energy band gap of greater than or equal to about 4 eV. For example, the organometallic salt may include a metal acetate, a metal benzoate, a metal acetoacetate, a metal acetylacetonate, or a metal stearate.

The electron transport layer included in the electron transport region ETR may include an electron transport material. The electron transport material may include a triazine-based compound or an anthracene-based compound. However, the disclosure is not limited thereto, and the electron transport material may include, for example, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP (2,9-dimethyl-4,7-diphenyl-1,10-phenanthroline), BPhen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (berylliumbis(benzoquinolin-10-olate), (9,10-di(naphthalene-2-yl)anthracene), TSPO1 (diphenyl(4-(triphenylsilyl)phenyl)phosphine oxide), TPM-TAZ (2,4,6-tris(3-(pyrimidin-5-yl)phenyl)-1,3,5-triazine), or a mixture thereof.

Each of the electron injection layers may independently have a thickness in a range of about 1 Å to about 500 Å. For example, each of the electron injection layers may independently have a thickness in a range of about 3 Å to about 300 Å. In case that the thickness of the electron injection layer satisfies the range as described above, a satisfactory electron injection characteristic may be obtained without a substantial increase in driving voltage.

Each of the electron transport layers may independently have a thickness in a range of about 100 Å to about 1,000 Å. For example, each of the electron transport layers may independently have a thickness in a range of about 150 Å to about 500 Å. In case that the thickness of the electron transport layer satisfies the range as described above, a satisfactory electron transport characteristic may be obtained without a substantial increase in driving voltage.

The hole blocking layer may be a layer that prevents holes from leaking from the hole transport region HTR to the electron transport region ETR. A thickness of the hole blocking layer may be in a range of about 10 Å to about 1,000 Å. The hole blocking layer may include, for example, at least one of BCP (2,9-dimethyl-4,7-diphenyl-1,10-phenanthroline), BPhen (4,7-diphenyl-1,10-phenanthroline), and T2T (2,4,6-tri([1,1′-biphenyl]-3-yl)-1,3,5-triazine), but is not limited thereto.

The emission layer EML may include at least one of an organic compound and a semiconductor compound, but is not limited thereto. In case that the emission layer EML contains an organic compound, the light emitting device may be an organic light emitting device.

The organic compound may include a host and a dopant. The semiconductor compound may be a quantum dot, for example, the light emitting device may be a quantum dot light emitting device. In another embodiment, the semiconductor compound may be an organic and/or inorganic perovskite.

A thickness of the emission layer EML may be in a range of about 0.1 nm to about 100 nm. For example, the thickness of the emission layer EML may be in a range of about 15 nm to about 50 nm. For example, in case that the emission layer EML emits blue light, a thickness of the blue emission layer may be in a range of about 15 nm to about 20 nm, in case that the emission layer emits green light, a thickness of the green emission layer may be in a range of about 20 nm to about 40 nm, and in case that the emission layer emits red light, a thickness of the red emission layer may be in a range of about 40 nm to about 50 nm. In case that the above-mentioned ranges are satisfied, the light emitting device may provide an excellent light emitting characteristic without a substantial increase in driving voltage.

The emission layer EML may include a host material and a dopant material. The emission layer EML may be formed by using a phosphorescent or fluorescent light emitting material as a dopant in a host material. The emission layer EML may be formed by including a thermally activated delayed fluorescence (TADF) dopant in a host material. In another embodiment, the emission layer EML may include a quantum dot material as a light emitting material. A core of the quantum dot may include a group II-VI compound, a group III-V compound, a group IV-VI compound, a group IV element, a group IV compound, or a combination thereof.

A color of light emitted from the emission layer EML may be determined by a combination of a host material and a dopant material, or a type of quantum dot material and a size of a core.

Although not particularly limited, the host material of the emission layer EML may include a fluoranthene derivative, a pyrene derivative, an arylacetylene derivative, an anthracene derivative, a fluorene derivative, a perylene derivative, a chrysene derivative, or the like. For example, the pyrene derivative, the perylene derivative, and the anthracene derivative may be selected.

Although not particularly limited, the dopant material of the emission layer EML may include styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), perylene and its derivatives (for example, 2,5,8,11-tetra-t-butylperylene (TBP)), pyrene and its derivatives (for example, 1,1-dipyrene, 1,4-dipyrenylbenzene, 1,4-bis(N,N-diphenylamino)pyrene), or N1,N6-di(naphthalen-2-yl)-N1,N6-diphenylpyrene-1,6-diamine).

A thickness of the second electrode E2 may be in a range of about 5 nm to about 20 nm. In case that the above-described range is satisfied, light absorption at the second electrode E2 may be minimized, and a satisfactory electron injection characteristic may be obtained without a substantial increase in driving voltage.

A capping layer CPL may be positioned on the second electrode E2 according to the embodiment.

The capping layer CPL may include multiple protrusions PR. The capping layer CPL may effectively emit or scatter light emitted from the light emitting device by including the protrusions PR. For example, the capping layer CPL may increase light extraction efficiency of the light emitting device.

The capping layer CPL may be formed through a deposition process, and organic materials deposited in the deposition process may aggregate to form the protrusions PR protruding from an upper surface of the capping layer CPL. A height of the protrusion PR may be greater than or equal to about 600 angstroms. An area of the protrusion PR may be greater than or equal to about 1 square micrometer in a plan view. In case that the height and area of the protrusion PR satisfy the above numerical ranges, effective light scattering may occur in the capping layer CPL.

The capping layer CPL according to the embodiment may include at least one of a compound represented by Chemical Formula 1 and a compound represented by Chemical Formula 2. The compound represented by Chemical Formula 1 and the compound represented by Chemical Formula 2 may form the capping layer CPL through a deposition process, and in the deposition process, some organic materials may aggregate to form the protrusions PR:

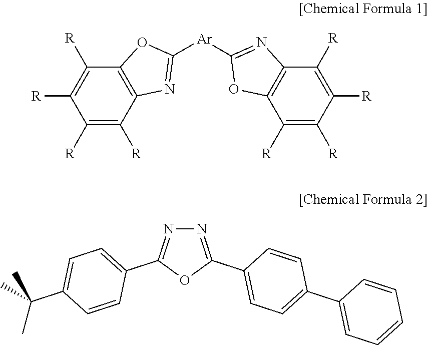

In Chemical Formula 1, Ar may be an aryl group having 6 to 20 carbon atoms, and each R may independently be one of hydrogen, an alkyl group having 1 to 20 carbon atoms, an aryl group having 6 to 20 carbon atoms, a heteroaryl group having 5 to 20 carbon atoms, a halogen, a nitro, CN, and an amine.

Hereinafter, a light emitting device according to an embodiment and a capping layer positioned on the light emitting device will be described with reference to FIG. 2 and FIG. 3. A description of the same components as those described in FIG. 1 will be omitted.

Referring to FIG. 2, a capping layer CPL according to an embodiment may include a first capping layer CPL1 and a second capping layer CPL2.

The first capping layer CPL1 may be positioned on the second electrode E2. The first capping layer CPL1 may include multiple protrusions PR1. The first capping layer CPL1 may effectively emit or scatter light emitted from the light emitting device by including the protrusions PR1. For example, the first capping layer CPL1 may increase the light extraction efficiency of the light emitting device.

The first capping layer CPL1 may be formed through a deposition process, and organic materials deposited in the deposition process may aggregate to form the protrusions PR1 protruding from an upper surface of the first capping layer CPL1. A height of the first protrusion PR1 may be greater than or equal to about 600 angstroms. An area of the first protrusion PR1 may be greater than or equal to about 1 square micrometer in a plan view. In case that the height and area of the first protrusion PR1 satisfy the above numerical ranges, effective light scattering may occur in the first capping layer CPL1.

A thickness of the first capping layer CPL1 may be in a range of about 300 angstroms to about 1,000 angstroms. In case that the thickness of the first capping layer CPL1 satisfies the above range, effective scattering may be achieved in the first capping layer CPL1, and the light extraction efficiency may be increased through the scattering.

The first capping layer CPL1 according to the embodiment may include at least one of a compound represented by Chemical Formula 1 and a compound represented by Chemical Formula 2. The compound represented by Chemical Formula 1 and the compound represented by Chemical Formula 2 may form the first capping layer CPL1 through a deposition process, and in the deposition process, some organic materials may aggregate to form the first protrusions PR1:

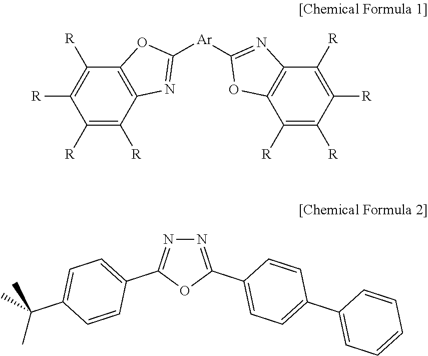

In Chemical Formula 1, Ar may be an aryl group having 6 to 20 carbon atoms, and each R may independently be hydrogen, an alkyl group having 1 to 20 carbon atoms, an aryl group having 6 to 20 carbon atoms, a heteroaryl group having 5 to 20 carbon atoms, a halogen, a nitro group, CN, or an amine group.

The second capping layer CPL2 may be disposed on the first capping layer CPL1. The second capping layer CPL2 may be provided to completely cover the first capping layer CPL1. In the process of forming the first capping layer CPL1, a portion of the second electrode E2 may be exposed as organic materials aggregate. The second capping layer CPL2 may completely cover the exposed second electrode E2 to provide a stable display device.

The second capping layer CPL2 may have any thickness to completely cover the first capping layer CPL1, and the thickness may be, for example, greater than or equal to 300 angstroms.

The second capping layer CPL2 may include a depositable organic material, and may include, for example, a compound represented by Chemical Formula 3:

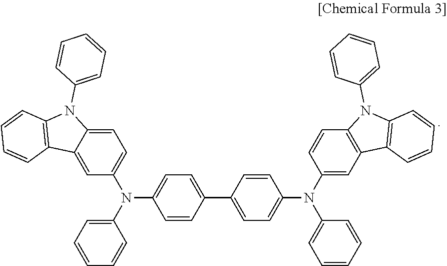 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

FIG. 2 illustrates a structure in which the first capping layer CPL1 and the second capping layer CPL2 are sequentially deposited, but the disclosure is not limited thereto, and as shown in FIG. 3, the second capping layer CPL2 and the first capping layer CPL1 may be sequentially stacked.

As shown in FIG. 3, in case that the second electrode E2, the second capping layer CPL2, and the first capping layer CPL1 are sequentially stacked, even if the lower layer of the first capping layer CPL1 is exposed due to an aggregation phenomenon during the manufacturing process of the first capping layer CPL1, since the second capping layer CPL2 including the organic material is exposed instead of the second electrode E2 being exposed, a stable display device may be provided.

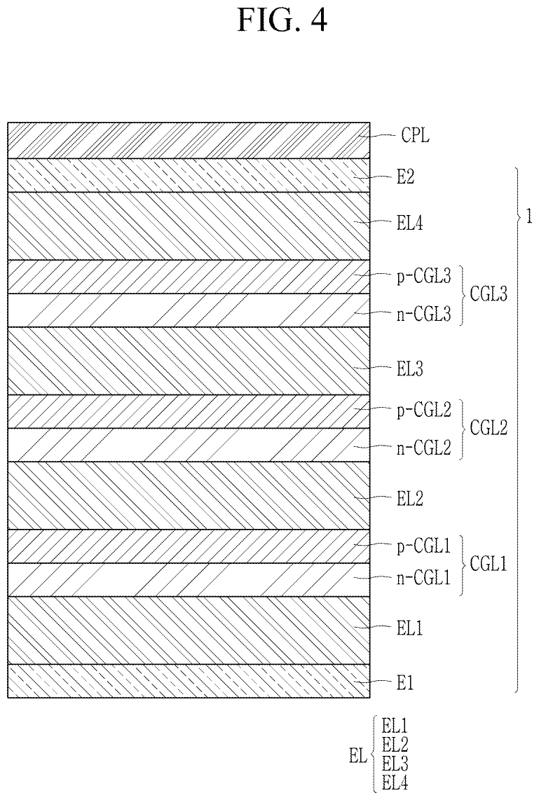

FIG. 4 illustrates a schematic cross-sectional view of a light emitting device and a capping layer according to an embodiment. FIG. 4 illustrates a schematic cross-sectional view of a light emitting device according to an embodiment. A description of the same constituent element as that described above will be omitted.

Referring to FIG. 4, the light emitting device 1 may include m light emitting units EL. The light emitting device 1 according to the embodiment may include m−1 charge generating layers CGL1, CGL2, and CGL3 interposed between adjacent light emitting units EL. The light emitting device 1 according to the embodiment may include the first charge generating layer CGL1 disposed between a first light emitting unit EL1 and a second light emitting unit EL2, the second charge generating layer CGL2 disposed between the second light emitting unit EL2 and a third light emitting unit EL3, and the third charge generating layer CGL3 disposed between the third light emitting unit EL3 and a fourth light emitting unit EL4. Although the specification shows the embodiment including three charge generating layers CGL1, CGL2, and CGL3, the disclosure is not limited thereto, and the number of charge generating layers may vary depending on the number of light emitting units EL.

Each of the charge generating layers CGL1, CGL2, and CGL3 may include n-type charge generating layers n-CGL1, n-CGL2, and n-CGL3 that provide electrons to the light emitting unit EL and p-type charge generating layers p-CGL1, p-CGL2, and p-CGL3 that provide holes to the light emitting unit EL. Although not shown, in another embodiment, a buffer layer may be disposed between the n-type charge generating layers n-CGL1, n-CGL2, and n-CGL3 and the p-type charge generating layers p-CGL1, p-CGL2, and p-CGL3.

The charge generating layers CGL1, CGL2, and CGL3 may generate charges (electrons and holes) by forming a complex through an oxidation-reduction reaction in case that a voltage is applied thereto. The charge generating layers CGL1, CGL2, and CGL3 may provide the generated charges to the light emitting units EL adjacent thereto. The charge generating layers CGL1, CGL2, and CGL3 may increase efficiency of a current generated in the light emitting unit EL, and may serve to adjust balance of charges between the adjacent light emitting units EL.

The first charge generating layer CGL1 may include a 1st n-type charge generating layer n-CGL1 and a 1st p-type charge generating layer p-CGL1. The 1st n-type charge generating layer n-CGL1 may be disposed adjacent to the first light emitting unit EL1, and the 1st p-type of charge generating layer p-CGL1 may be disposed adjacent to the second light emitting unit EL2. The second charge generating layer CGL2 may include a 2nd n-type charge generating layer n-CGL2 and a 2nd p-type charge generating layer p-CGL2. The 2nd n-type charge generating layer n-CGL2 may be disposed adjacent to the second light emitting unit EL2, and the 2nd p-type charge generating layer p-CGL2 may be disposed adjacent to the third light emitting unit EL3. The third charge generating layer CGL3 may include a 3rd n-type charge generating layer n-CGL3 and a 3rd p-type charge generating layer p-CGL3. The 3rd n-type charge generating layer n-CGL3 may be disposed adjacent to the third light emitting unit EL3, and the 3rd p-type charge generating layer p-CGL3 may be disposed adjacent to the fourth light emitting unit EL4.

The second electrode E2 may be disposed on the m-th light emitting unit EL. The second electrode E2 may be a cathode, which is an electron injection electrode.

A capping layer CPL may be positioned on the second electrode E2. The capping layer CPL may be the capping layer described with reference to FIG. 1, the capping layer described with reference to FIG. 2, or the capping layer described with reference to FIG. 3.

The above-described light emitting device 1 may include the following material according to the embodiment, but is not limited thereto. For example, the light emitting device 1 according to the embodiment may include the light emitting units EL emitting different lights. At least one of the light emitting units EL may emit a first color, and at least one of the remaining light emitting units EL may emit a second color. The first color and the second color may be different. For example, the light emitting device 1 may include a first light emitting unit EL1, a second light emitting unit EL2, and a third light emitting unit EL3, each emits blue light, and may include a fourth light emitting unit EL4 that emits green light.

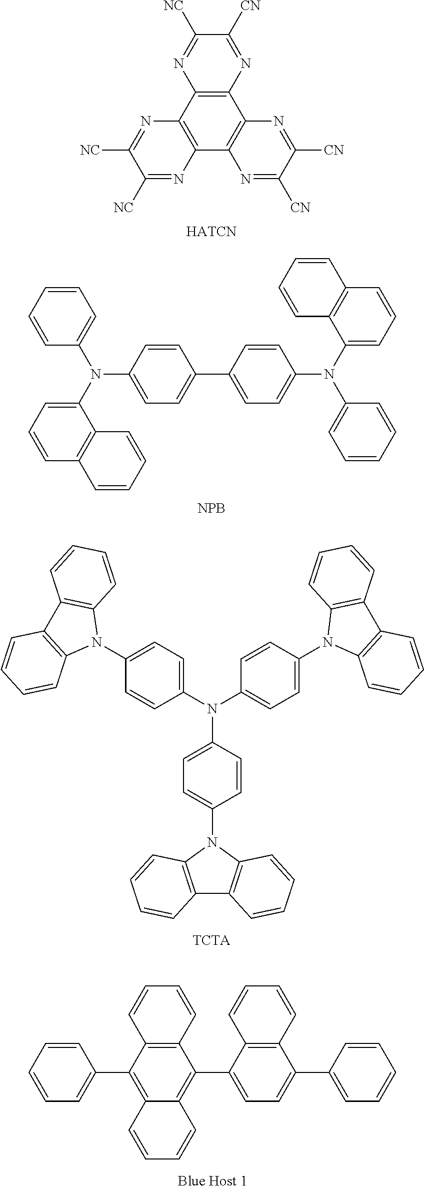

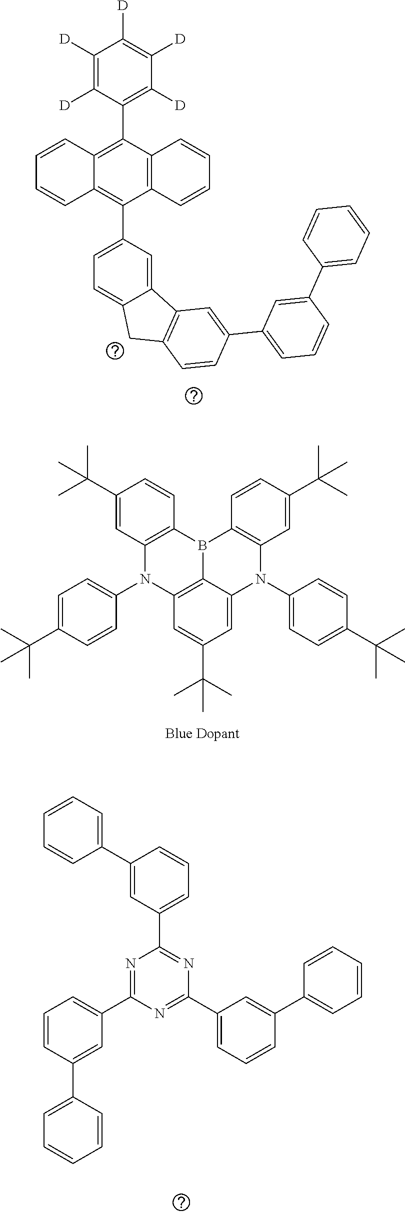 [SMILES: [2H]c1c([2H])c([2H])c(-c2c3ccccc3c(-c3ccc4c(c3)-c3cc(-c5cccc(-c6ccccc6)c5)ccc3C4)c3ccccc23)c([2H])c1[2H] ; CC(C)(C)c1ccc(N2c3cc(C(C)(C)C)ccc3B3c4ccc(C(C)(C)C)cc4N(c4ccc(C(C)(C)C)cc4)c4cc(C(C)(C)C)cc2c43)cc1 ; c1ccc(-c2cccc(-c3nc(-c4cccc(-c5ccccc5)c4)nc(-c4cccc(-c5ccccc5)c4)n3)c2)cc1]

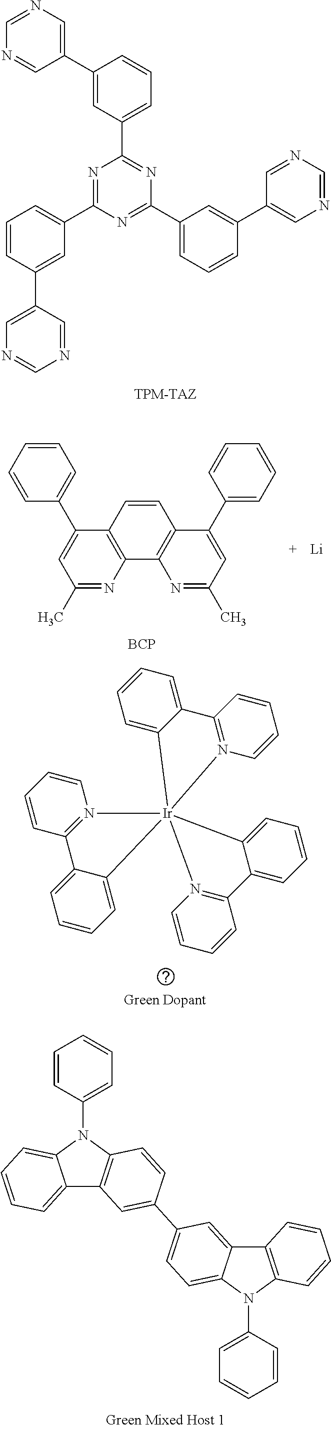

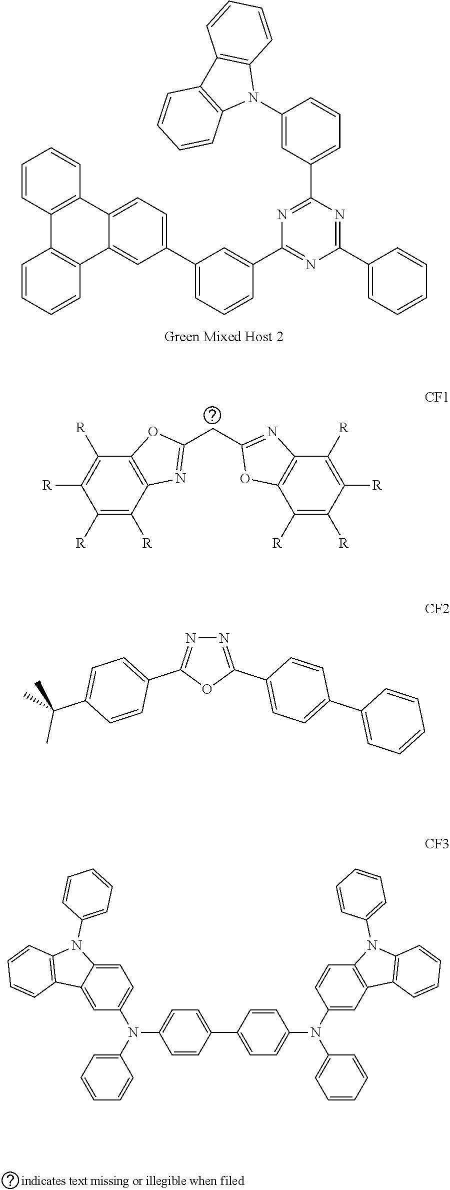

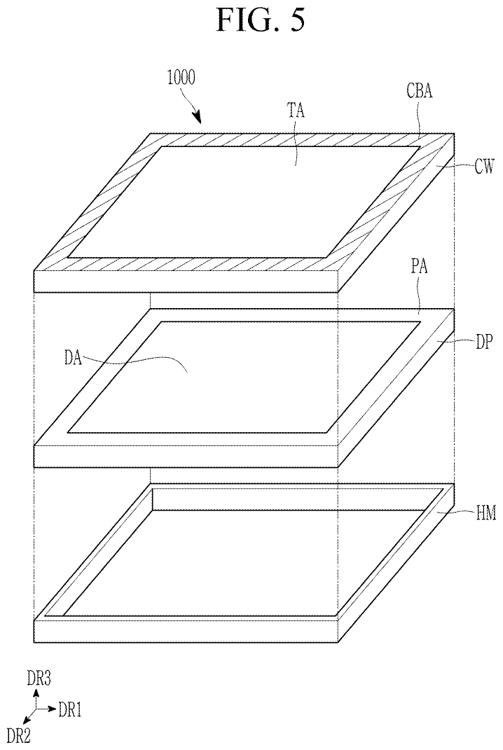

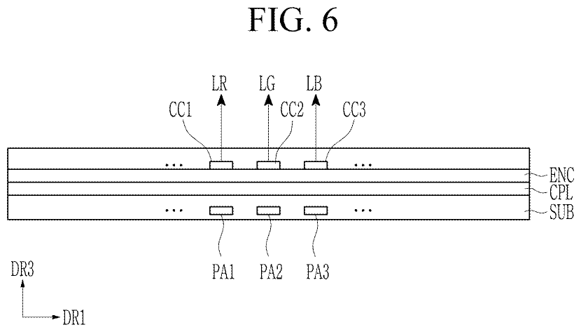

Hereinafter, a display device according to an embodiment will be described with reference to FIG. 5 and FIG. 6. FIG. 5 illustrates an exploded perspective view of a display device according to an embodiment, and FIG. 6 illustrates a schematic cross-sectional view of a display panel according to an embodiment.

Referring to FIG. 5, the display device 1000 according to the embodiment may include a cover window CW, a display panel DP, and a housing HM.

The cover window CW may include an insulating panel. For example, the cover window CW may be made of glass, plastic, or a combination thereof.

A front surface of the cover window CW may define a front surface of a display device 1000. A transmission area TA may be an optically transparent area. For example, the transmission area TA may be an area having visible ray transmittance of greater than or equal to about 90%.

A blocking area CBA may define a shape of the transmission area TA. The blocking area CBA may be disposed adjacent to the transmission area TA, and may surround the transmission area TA. The blocking area CBA may be an area having relatively low light transmittance compared to the transmission area TA. The blocking area CBA may include an opaque material that blocks light. The blocking area CBA may have a predetermined (or selectable) color. The blocking area CBA may be defined by a bezel layer provided separately from a transparent substrate defining the transmission area TA, or may be defined by an ink layer formed by being inserted into or coloring the transparent substrate.

A surface of the display panel DP on which an image is displayed may be parallel to a surface defined by a first direction DR1 and a second direction DR2. A third direction DR3 may be a normal direction of the surface on which the image is displayed, for example, a thickness direction of the display panel DP. A front surface (or upper surface) and a back surface (or lower surface) of each member may be determined by the third direction DR3. However, directions indicated by the first to third directions DR1, DR2, and DR3 are relative concepts, and thus they may be changed into other directions.

The display panel DP may be a flat rigid display panel, but is not limited thereto, and may be a flexible display panel. The display panel DP may be an organic light emitting display panel. However, the type of the display panel DP is not limited thereto, and the display panel may be formed as various types of panels. For example, the display panel DP may be a liquid crystal panel, an electrophoretic display panel, an electrowetting display panel, or the like. The display panel DP may be formed as a next-generation display panel such as a micro light emitting diode display panel, a quantum dot light emitting diode display panel, or a quantum dot organic light emitting diode display panel.

The micro light emitting diode (Micro LED) display panel may be formed in such a way that the light emitting diode having a size in a range of about 10 to about 100 micrometers configures each pixel. The micro light emitting diode display panel has advantages in which an inorganic material is used, and a backlight may be omitted, and that has a fast reaction speed, may implement high brightness with low power, and is not broken when bent. The quantum dot light emitting diode display panel may be formed by attaching a film including quantum dots or forming a material including quantum dots. The quantum dots may be particles that are made of inorganic materials such as indium and cadmium, emit light by themselves, and have a diameter of several nanometers or less. By controlling a particle size of the quantum dots, light of a desired color may be displayed. The quantum dot organic light emitting diode display panel may have a structure in which a blue organic light emitting diode is used as a light source, and a film including red and green quantum dots is attached thereon, or a material including red and green quantum dots is deposited to realize color. The display panel DP according to the embodiment may be configured as various other display panels.

As shown in FIG. 5, the display panel DP may include a display area DA in which an image is displayed, and a non-display area PA disposed adjacent to the display area DA. The non-display area PA may be an area in which no image is displayed. The display area DA may have, for example, a quadrangular shape, and the non-display area PA may have a shape surrounding the display area DA in a plan view. However, the disclosure is not limited thereto, and the shapes of the display area DA and the non-display area PA may be relatively designed.

The housing HM may provide an inner space. The display panel DP may be mounted inside the housing HM. In addition to the display panel DP, various electronic components, for example, a power supply part, a storage device, and an audio input/output module, may be mounted inside the housing HM.

Hereinafter, a display panel according to an embodiment will be described with reference to FIG. 6. Referring to FIG. 6 together with FIG. 5, multiple of pixels PA1, PA2, and PA3 may be formed on a substrate SUB corresponding to the display area DA of the display panel DP. Each of the pixels PA1, PA2, and PA3 may include multiple transistors and a light emitting device connected thereto.

The above-described capping layer CPL and an encapsulation layer ENC may be disposed on the pixels PA1, PA2, and PA3. The display area DA may be protected from external air or moisture by the encapsulation layer ENC. The encapsulation layer ENC may be provided on the entire display area DA, or may be partially disposed on the non-display area PA.

A first color conversion part CC1, a second color conversion part CC2, and a transmission part CC3 may be positioned on the encapsulation layer ENC. The first color conversion part CC1 may overlap the first pixel PA1, the second color conversion part CC2 may overlap the second pixel PA2, and the transmission part CC3 may overlap the third pixel PA3 in the third direction DR3.

Light emitted from the first pixel PA1 may pass through the first color conversion part CC1 to provide red light (LR). Light emitted from the second pixel PA2 may pass through the second color conversion part CC2 to provide green light (LG). Light emitted from the third pixel PA3 may pass through the transmission part CC3 to provide blue light (LB).

Hereinafter, the efficiency and lifespan of the light emitting device according to the embodiment will be described with reference to Table 1 and Table 2.

Referring to Table 1, Comparative Example 1 includes a capping layer including only a compound represented by Chemical Formula 3. Comparative Example 2 includes a capping layer including a compound expressed by Chemical Formula 1, and a thickness of the capping layer is 200 angstroms. Example 1 is different from Comparative Example 2 in thickness, and a thickness of the capping layer is 400 angstroms. Example 2 is different from Example 1 only in thickness, and a thickness of the capping layer is 600 angstroms. Example 3 is different from Example 1 only in thickness, and a thickness of the capping layer is 800 angstroms.

Comparative Example 3 is a case in which the second capping layer is positioned on the first capping layer, the thickness of the second capping layer is 400 angstroms, and the thickness of the first capping layer is 200 angstroms. The first capping layer includes the compound represented by Chemical Formula 1, and the second capping layer includes the compound represented by Chemical Formula 3. Example 4 is an example in which only the thickness of the first capping layer is different from that of Comparative Example 3, and the thickness of the first capping layer is 400 angstroms. Example 5 is an example in which only the thickness of the first capping layer is different from that of Example 4, and the thickness of the first capping layer is 600 angstroms. Example 6 is an example in which only the thickness of the first capping layer is different from that of Example 4, and the thickness of the first capping layer is 800 angstroms.

Comparative Example 4 is an example in which the positions of the first capping layer and the second capping layer in Comparative Example 3 are changed. Example 7 is an example in which the positions of the first capping layer and the second capping layer in Example 4 are changed. Example 8 is an example in which the positions of the first capping layer and the second capping layer in Example 5 are changed. Example 9 is an example in which the positions of the first capping layer and the second capping layer in Example 6 are changed.

Referring to Example 1 to Example 9, it was confirmed that, while they had the same luminance, the efficiency thereof was improved by about 8% and the lifespan thereof was improved by up to 20%, compared to Comparative Example 1 to Comparative Example 4.

It was confirmed that the height of the protrusions included in the capping layer of Comparative Example 2 was about 400 angstroms, the height of the protrusions of Example 1 was about 800 angstroms, the height of the protrusions of Example 2 was about 1,000 angstroms, and the height of the protrusions of Example 3 was about 1,000 angstroms or more.

In Comparative Example 1, the material included in the capping layer did not form a protrusion, and in Comparative Example 2 to Comparative Example 4, since the thickness of the first capping layer was significantly thin, it was difficult to form protrusions that effectively generate scattering, and thus it was confirmed that the efficiency or lifespan increase was not effective. For example, it was confirmed that the height of the protrusions needs to be greater than or equal to at least 600 angstroms to provide effective scattering.

TABLE 1

| | Efficiency | | |
|---|---|---|---|
| Structure | (Cd/A) | Lifespan | Luminance |
| Comparative Example 1 | 100% | 100% | 1500 nit |
| Comparative Example 2 | 99% | 101% | 1500 nit |
| Example 1 | 105% | 111% | 1500 nit |
| Example 2 | 107% | 115% | 1500 nit |
| Example 3 | 107% | 117% | 1500 nit |
| Comparative Example 3 | 100% | 100% | 1500 nit |
| Example 4 | 106% | 113% | 1500 nit |
| Example 5 | 107% | 118% | 1500 nit |
| Example 6 | 107% | 120% | 1500 nit |
| Comparative Example 4 | 99% | 99% | 1500 nit |
| Example 7 | 106% | 118% | 1500 nit |
| Example 8 | 108% | 116% | 1500 nit |
| Example 9 | 107% | 117% | 1500 nit |

Referring to Table 2, Comparative Example 5 includes only the capping layer including the compound represented by Chemical Formula 3. Comparative Example 6 includes a capping layer including a compound represented by Chemical Formula 2, and a thickness of the capping layer is 200 angstroms. Example 10 is different from Comparative Example 6 only in thickness, and a thickness of the family layer is 400 angstroms. Example 11 is different from Example 10 only in thickness, and a thickness of the capping layer is 600 angstroms. Example 12 is different from Example 10 only in thickness, and a thickness of the capping layer is 800 angstroms.

Comparative Example 7 is a case in which the second capping layer is positioned on the first capping layer, the thickness of the second capping layer is 400 angstroms, and the thickness of the first capping layer is 200 angstroms. The first capping layer includes the compound represented by Chemical Formula 2, and the second capping layer includes the compound represented by Chemical Formula 3. Example 13 is an example in which only the thickness of the first capping layer is different from that of Comparative Example 7, and the thickness of the first capping layer is 400 angstroms. Example 14 is an example in which only the thickness of the first capping layer is different from that of Example 13, and the thickness of the first capping layer is 600 angstroms. Example 15 is an example in which only the thickness of the first capping layer is different from that of Example 13, and the thickness of the first capping layer is 800 angstroms.

Comparative Example 8 is an example in which the positions of the first capping layer and the second capping layer in Comparative Example 7 are changed. Example 16 is an example in which the positions of the first capping layer and the second capping layer in Example 13 are changed. Example 17 is an example in which the positions of the first capping layer and the second capping layer in Example 14 are changed. Example 18 is an example in which the positions of the first capping layer and the second capping layer are changed in Example 15.

Referring to Example 10 to Example 18, it was seen that, while they had the same luminance, the efficiency thereof was improved by about 6% and the lifespan thereof was improved by up to 16%, compared to Comparative Example 5 to Comparative Example 8.

It was confirmed that the height of the protrusions of Comparative Example 6 was about 300 angstroms, the height of the protrusions of Example 10 was about 600 angstroms, the height of the protrusions of Example 11 was about 900 angstroms, and the height of the protrusions of Example 12 was about 900 angstroms or more.

In Comparative Example 5, the material included in the capping layer did not form a protrusion, and in Comparative Example 6 to Comparative Example 8, since the thickness of the first capping layer was significantly thin, it was difficult to form protrusions that effectively generate scattering, and thus it was confirmed that the efficiency or lifespan increase was not effective. For example, it was confirmed that the height of the protrusions needs be at least 600 angstroms or more to provide effective scattering.

TABLE 2

| | Efficiency | | |
|---|---|---|---|
| Structure | (Cd/A) | Lifespan | Luminance |
| Comparative Example 5 | 100% | 100% | 1500 nit |
| Comparative Example 6 | 100% | 102% | 1500 nit |
| Example 10 | 103% | 110% | 1500 nit |
| Example 11 | 104% | 115% | 1500 nit |
| Example 12 | 104% | 115% | 1500 nit |
| Comparative Example 7 | 99% | 100% | 1500 nit |
| Example 13 | 104% | 110% | 1500 nit |
| Example 14 | 104% | 113% | 1500 nit |
| Example 15 | 104% | 115% | 1500 nit |
| Comparative Example 8 | 100% | 99% | 1500 nit |
| Example 16 | 104% | 113% | 1500 nit |
| Example 17 | 106% | 116% | 1500 nit |
| Example 18 | 105% | 115% | 1500 nit |

For example, in the case of the display device including the capping layer including the compound represented by Chemical Formula 1 and/or the compound represented by Chemical Formula 2 as described above, the luminous efficiency and lifespan of the light emitting device may be increased.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display device comprising:
a light emitting device disposed on a substrate;
a capping layer disposed on the light emitting device; and
an encapsulation layer disposed on the capping layer, wherein
the capping layer includes a first surface facing the encapsulation layer,
the first surface of the capping layer includes a protrusion protruding toward the encapsulation layer, and
a height of the protrusion is greater than or equal to about 600 angstroms in a cross-sectional view.

2. The display device of claim 1, wherein an area of the protrusion is greater than or equal to about 1 square micrometer in a plan view.

3. The display device of claim 1, wherein the capping layer includes at least one of a compound represented by Chemical Formula 1 and a compound represented by Chemical Formula 2: 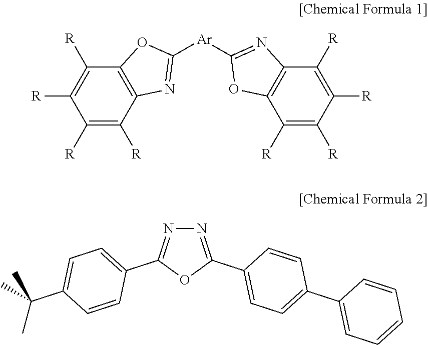
wherein in Chemical Formula 1,
Ar is an aryl group having 6 to 20 carbon atoms, and
each R is independently hydrogen, an alkyl group having 1 to 20 carbon atoms, an aryl group having 6 to 20 carbon atoms, a heteroaryl group having 5 to 20 carbon atoms, a halogen, a nitro group, CN, or an amine group.

4. The display device of claim 1, wherein a thickness of the capping layer is in a range of about 300 angstroms to about 1,000 angstroms in a cross-sectional view.

5. A display device comprising:
a light emitting device disposed on a substrate;
a capping layer disposed on the light emitting device; and
an encapsulation layer disposed on the capping layer, wherein
the capping layer includes a first capping layer and a second capping layer,
the first capping layer includes a protrusion, and
each of the first capping layer and the second capping layer includes an organic material.

6. The display device of claim 5, wherein the light emitting device includes:
a first electrode;
an emission layer disposed on the first electrode; and
a second electrode disposed on the emission layer.

7. The display device of claim 6, wherein
the first capping layer is disposed on the second electrode, and
the second capping layer is disposed on the first capping layer.

8. The display device of claim 7, wherein the second capping layer covers the first capping layer.

9. The display device of claim 7, wherein
the first capping layer exposes a portion of the second electrode, and
the second capping layer covers the second electrode and the first capping layer.

10. The display device of claim 6, wherein
the second capping layer is disposed on the second electrode, and
the first capping layer is disposed on the second capping layer.

11. The display device of claim 10, wherein the first capping layer exposes a portion of the second capping layer.

12. The display device of claim 5, wherein the first capping layer includes at least one of a compound represented by Chemical Formula 1 and a compound represented by Chemical Formula 2: 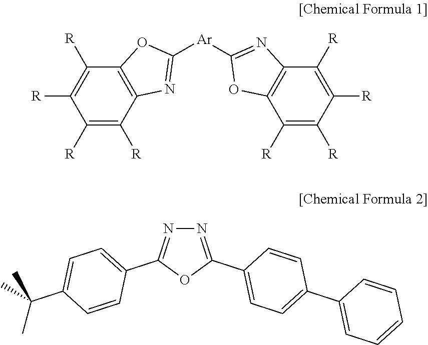
wherein in Chemical Formula 1,
Ar is an aryl group having 6 to 20 carbon atoms, and
each R is independently hydrogen, an alkyl group having 1 to 20 carbon atoms, an aryl group having 6 to 20 carbon atoms, a heteroaryl group having 5 to 20 carbon atoms, a halogen, a nitro group, CN, or an amine group.

13. The display device of claim 5, wherein the second capping layer includes a compound represented by Chemical Formula 3:

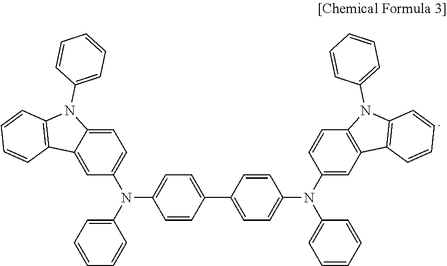 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

14. The display device of claim 5, wherein
an area of the protrusion is greater than or equal to about 1 square micrometer in a plan view, and
a height of the protrusion is greater than or equal to about 600 angstroms in a cross-sectional view.

15. The display device of claim 5, wherein a thickness of the first capping layer is in a range of about 300 angstroms to about 1,000 angstroms in a cross-sectional view.

16. The display device of claim 5, wherein a thickness of the second capping layer is greater than or equal to about 300 angstroms in a cross-sectional view.

17. The display device of claim 5, wherein the light emitting device includes:
a first light emitting device that emits light of a first color; and
a second light emitting device that emits light of a second color.

18. The display device of claim 17, wherein the first color and the second color are different.

19. The display device of claim 17, wherein
the first light emitting device emits blue light, and
the second light emitting device emits green light.

20. The display device of claim 17, wherein
the first light emitting device includes a first emission layer,
the second light emitting device includes a second emission layer, and
at least one of the first emission layer and the second emission layer includes a quantum dot.
